(19) United States
(12) Patent Application Publication
(10) Pub. No.: US 2020/0343402 A1
(43) Pub. Date: Oct. 29, 2020

(54) ABSORBER LAYERS WITH MERCURY FOR PHOTOVOLTAIC DEVICES AND METHODS FOR FORMING THE SAME

(71) Applicant: First Solar, Inc., Tempe, AZ (US)

(72) Inventors: Paul King, San Jose, CA (US); Xiaoping Li, Santa Clara, CA (US); Roger Malik, Santa Clara, CA (US); Gang Xiong, Santa Clara, CA (US); Wei Zhang, San Jose, CA (US)

(73) Assignee: First Solar, Inc., Tempe, AZ (US)

(21) Appl. No.: 16/956,366

(22) PCT Filed: Dec. 20, 2018
(86) PCT No.: PCT/US2018/066742

§ 371 Date: Jun. 19, 2020

Related U.S. Application Data
(60) Provisional application No. 62/609,726, filed on Dec. 22, 2017.

(51) Int. Cl. H01L 31/103; H01L 31/0296; H01L 31/18

(52) U.S. Cl. CPC H01L 31/1032; H01L 31/1832; H01L 31/02966

(57) ABSTRACT

According to the embodiments provided herein, a photovoltaic device can have an energy side configured to be exposed to a light source. The photovoltaic device can include an absorber layer. The absorber layer can include a first surface facing the energy side and a thickness defined between the first surface and a second surface. The absorber layer can include mercury having a mole fraction y, cadmium having a mole fraction (1−y), and tellurium. The mole fraction y of the mercury can vary through the thickness of the absorber layer with distance from the first surface of the absorber layer.

### BACKGROUND

The present specification generally relates to photovoltaic devices and, more specifically, absorber layers comprising mercury for use in photovoltaic devices.

A photovoltaic device generates electrical power by converting light into electricity using semiconductor materials that exhibit the photovoltaic effect. Certain types of semiconductor material can be difficult to utilize. For example, some chemicals provided in the semiconductor material can have both desirable properties and undesirable properties. The addition of certain chemicals such as, for example, selenium, into an absorber layer can increase the number of defects within the absorber layer. Accordingly, materials added to the photovoltaic device with the intent of improving efficiency, can ultimately decrease efficiency.

Accordingly, a need exists for alternative absorber layers for use photovoltaic devices.

### SUMMARY

The embodiments provided herein relate to absorber layers comprising mercury and methods for forming the same. These and additional features provided by the embodiments described herein will be more fully understood in view of the following detailed description, in conjunction with the drawings.

### BRIEF DESCRIPTION OF THE DRAWINGS

The embodiments set forth in the drawings are illustrative and exemplary in nature and not intended to limit the subject matter defined by the claims. The following detailed description of the illustrative embodiments can be understood when read in conjunction with the following drawings, where like structure is indicated with like reference numerals and in which:

FIG. 1 schematically depicts a photovoltaic device according to one or more embodiments shown and described herein;

FIG. 2 schematically depicts a substrate according to one or more embodiments shown and described herein;

FIG. 3 graphically depicts band gaps for Hg_{y}Cd_{1-y}Te compounds according to one or more embodiments shown and described herein;

FIG. 4 graphically depicts band gaps for Hg_{y}Cd_{1-y}SeₓTe₁₋ₓ compounds according to one or more embodiments shown and described herein;

FIG. 5 graphically depicts band gaps for Hg_{y}Cd_{1-y}SeₓTe₁₋ₓ compounds as a surface plot according to one or more embodiments shown and described herein;

FIG. 6 schematically depicts a photovoltaic device according to one or more embodiments shown and described herein;

FIG. 7 schematically depicts a method for forming an absorber layer according to one or more embodiments shown and described herein;

FIG. 8 schematically depicts a precursor layer stack according to one or more embodiments shown and described herein;

FIG. 9 graphically depicts uncalibrated quantum efficiencies for photovoltaic devices according to one or more embodiments shown and described herein;

FIG. 10 graphically depicts mercury concentration of an absorber layer determined using Time-of-Flight Secondary Ion Mass Spectrometry according to one or more embodiments shown and described herein; and

FIG. 11 graphically depicts mole fractions of an Hg_{y}Cd_{1-y}SeₓTe₁₋ₓ compound determined using Time-of-Flight Secondary Ion Mass Spectrometry according to one or more embodiments shown and described herein.

### DETAILED DESCRIPTION

Embodiments of a photovoltaic device for generating electrical power from light are described herein. The photovoltaic device generally includes an absorber layer formed from a semiconductor material comprising mercury such as, for example, Hg_{y}Cd_{1-y}Te, where 0<y<1, or Hg_{y}Cd_{1-y}SeₓTe₁₋ₓ, where 0<y<1 and 0<x<1. Various embodiments of the photovoltaic device and methods for forming the photovoltaic device will be described in more detail herein.

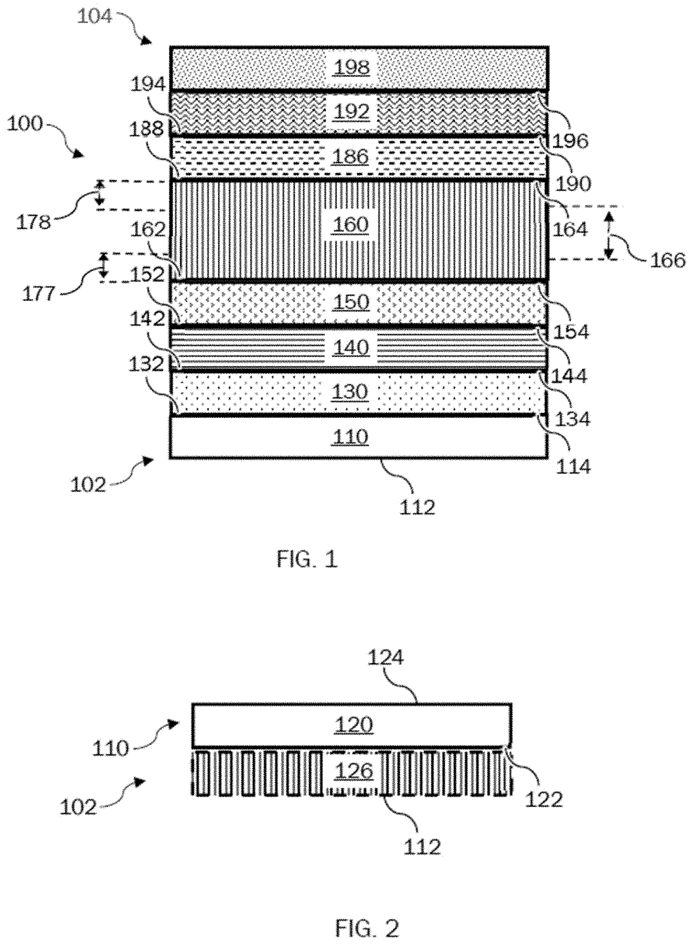

Referring now to FIG. 1, an embodiment of a photovoltaic device 100 is schematically depicted. The photovoltaic device 100 can be configured to receive light and transform light into electrical signals, e.g., photons can be absorbed from the light and transformed into electrical signals via the photovoltaic effect. Accordingly, the photovoltaic device 100 can define an energy side 102 configured to be exposed to a light source such as, for example, the sun. The photovoltaic device 100 can also define an opposing side 104 offset from the energy side 102 such as, for example, by a plurality of material layers. It is noted that the term “light” can refer to various wavelengths of the electromagnetic spectrum such as, but not limited to, wavelengths in the ultraviolet (UV), infrared (IR), and visible portions of the electromagnetic spectrum. The photovoltaic device 100 can include a plurality of layers disposed between the energy side 102 and the opposing side 104. As used herein, the term “layer” refers to a thickness of material provided upon a surface. Each layer can cover all or any portion of the surface.

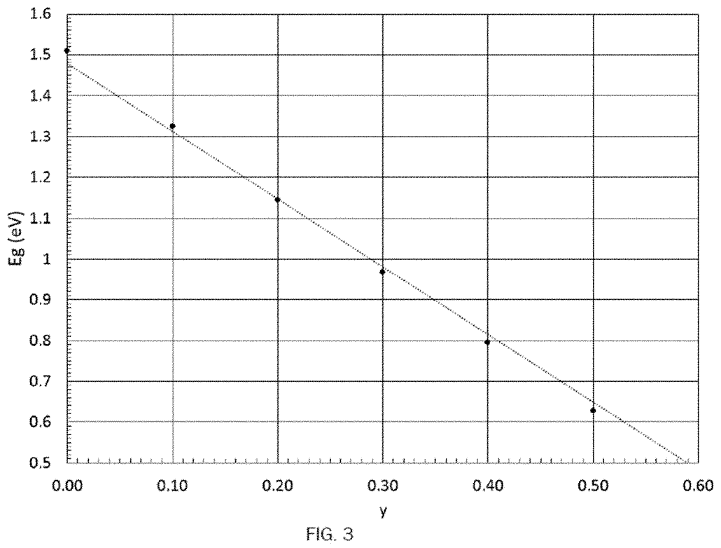

The photovoltaic device 100 can include a substrate 110 configured to facilitate the transmission of light into the photovoltaic device 100. The substrate 110 can be disposed at the energy side 102 of the photovoltaic device 100. Referring collectively to FIGS. 1 and 2, the substrate 110 can have a first surface 112 substantially facing the energy side 102 of the photovoltaic device 100 and a second surface 114 substantially facing the opposing side 104 of the photovoltaic device 100. One or more layers of material can be disposed between the first surface 112 and the second surface 114 of the substrate 110.

The substrate 110 can include a transparent layer 120 having a first surface 122 substantially facing the energy side 102 of the photovoltaic device 100 and a second surface 124 substantially facing the opposing side 104 of the photovoltaic device 100. In some embodiments, the second surface 124 of the transparent layer 120 can form the second surface 114 of the substrate 110. The transparent layer 120 can be formed from a substantially transparent material such as, for example, glass. Suitable glass can include soda-lime glass, or any glass with reduced iron content. The transparent layer 120 can have any suitable transmittance, including about 350 nm to about 1,300 nm in some embodiments, or about 450 nm to about 800 nm in other embodiments. The transparent layer 120 may also have any suitable transmission percentage, including, for example, more than about 50% in one embodiment, more than about 60% in another embodiment, more than about 70% in yet another embodiment, more than about 80% in a further embodiment, or more than about 85% in still a further embodiment. In one embodiment, transparent layer 120 can be formed from a glass with about 90% transmittance. Optionally, the substrate 110 can include a coating 126 applied to the first surface 122 of the transparent layer 120. The coating 126 can be configured to interact with light or to improve durability of the substrate 110 such as, but not limited to, an antireflective coating, an antisoiling coating, or a combination thereof.

Referring again to FIG. 1, the photovoltaic device 100 can include a barrier layer 130 configured to mitigate diffusion of contaminants (e.g. sodium) from the substrate 110, which could result in degradation or delamination. The barrier layer 130 can have a first surface 132 substantially facing the energy side 102 of the photovoltaic device 100 and a second surface 134 substantially facing the opposing side 104 of the photovoltaic device 100. In some embodiments, the barrier layer 130 can be provided adjacent to the substrate 110. For example, the first surface 132 of the barrier layer 130 can be provided upon the second surface 114 of the substrate 100. The phrase “adjacent to,” as used herein, means that two layers are disposed contiguously and without any intervening materials between at least a portion of the layers.

Generally, the barrier layer 130 can be substantially transparent, thermally stable, with a reduced number of pin holes and having high sodium-blocking capability, and good adhesive properties. Alternatively or additionally, the barrier layer 130 can be configured to apply color suppression to light. The barrier layer 130 can include one or more layers of suitable material, including, but not limited to, tin oxide, silicon dioxide, aluminum-doped silicon oxide, silicon oxide, silicon nitride, or aluminum oxide. The barrier layer 130 can have any suitable thickness bounded by the first surface 132 and the second surface 134, including, for example, more than about 500 Å in one embodiment, more than about 750 Å in another embodiment, or less than about 1200 Å in a further embodiment.

Referring still to FIG. 1, the photovoltaic device 100 can include a transparent conductive oxide (TCO) layer 140 configured to provide electrical contact to transport charge carriers generated by the photovoltaic device 100. The TCO layer 140 can have a first surface 142 substantially facing the energy side 102 of the photovoltaic device 100 and a second surface 144 substantially facing the opposing side 104 of the photovoltaic device 100. In some embodiments, the TCO layer 140 can be provided adjacent to the barrier layer 130. For example, the first surface 142 of the TCO layer 140 can be provided upon the second surface 134 of the barrier layer 130. Generally, the TCO layer 140 can be formed from one or more layers of n-type semiconductor material that is substantially transparent and has a wide band gap. Specifically, the wide band gap can have a larger energy value compared to the energy of the photons of the light, which can mitigate undesired absorption of light. The TCO layer 140 can include one or more layers of suitable material, including, but not limited to, tin dioxide, doped tin dioxide (e.g., F—SnO₂), indium tin oxide, or cadmium stannate.

The photovoltaic device 100 can include a buffer layer 150 configured to provide an insulating layer between the TCO layer 140 and any adjacent semiconductor layers. The buffer layer 150 can have a first surface 152 substantially facing the energy side 102 of the photovoltaic device 100 and a second surface 154 substantially facing the opposing side 104 of the photovoltaic device 100. In some embodiments, the buffer layer 150 can be provided adjacent to the TCO layer 140. For example, the first surface 152 of the buffer layer 150 can be provided upon the second surface 144 of the TCO layer 140. The buffer layer 140 may include material having higher resistivity than the TCO later 140, including, but not limited to, intrinsic tin dioxide, zinc magnesium oxide (e.g., Zn₁₋ₓMgₓO), silicon dioxide (SnO₂), aluminum oxide (Al₂O₃), aluminum nitride (AlN), zinc tin oxide, zinc oxide, tin silicon oxide, or any combination thereof. In some embodiments, the material of the buffer layer 150 can be tailored according to the band gap of an adjacent semiconductor layer (e.g., the band gap can be greater than or equal to the band gap of an absorber). The buffer layer 150 may have any suitable thickness between the first surface 152 and the second surface 154, including, for example, more than about 100 Å in one embodiment, between about 100 Å and about 800 Å in another embodiment, or between about 150 Å and about 600 Å in a further embodiment.

Referring again to FIG. 1, the photovoltaic device 100 can include an absorber layer 160 configured to cooperate with another layer and form a p-n junction within the photovoltaic device 100. Accordingly, absorbed photons of the light can generate electron-hole pairs and generate carrier flow, which can yield electrical power. The absorber layer 160 can have a first surface 162 substantially facing the energy side 102 of the photovoltaic device 100 and a second surface 164 substantially facing the opposing side 104 of the photovoltaic device 100. A thickness of the absorber layer 160 can be defined between the first surface 162 and the second surface 164. The thickness of the absorber layer 160 can be between about 0.5 μm to about 10 μm such as, for example, between about 1 μm to about 7 μm in one embodiment, or between about 2 μm to about 5 μm in another embodiment.

According to the embodiments described herein, the absorber layer 160 can be formed from a p-type semiconductor material having an excess of positive charge carriers, i.e., holes or acceptors. The absorber layer 160 can include any suitable p-type semiconductor material such as group II-VI semiconductors. Specific examples include, but are not limited to, semiconductor materials comprising mercury, cadmium, tellurium, selenium, or any combination thereof. Suitable examples include, but are not limited to, ternaries of mercury, cadmium, and tellurium (e.g., Hg_{y}Cd_{1-y}Se), quaternaries comprising mercury, cadmium, selenium and tellurium (e.g., Hg_{y}Cd_{1-y}SeₓTe₁₋ₓ), or a compound comprising mercury, cadmium, selenium, tellurium, and one or more additional element.

In embodiments where the absorber layer 160 comprises tellurium and cadmium, the atomic percent of the tellurium can be greater than about 25 atomic percent and less than about 50 atomic percent such as, for example, greater than about 30 atomic percent and less than about 50 atomic percent in one embodiment, greater than about 40 atomic percent and less than about 50 atomic percent in a further embodiment, or greater than about 47 atomic percent and less than about 50 atomic percent in yet another embodiment. It is noted that the atomic percent described herein is representative of the entirety of the absorber layer 160, the atomic percentage of material at a particular location within the absorber layer 160 can vary with thickness compared to the overall composition of the absorber layer 160.

In embodiments where the absorber layer 160 comprises selenium and tellurium, the atomic percent of the selenium in the absorber layer 160 can be greater than about 0 atomic percent and less than about 25 atomic percent such as, for example, greater than about 1 atomic percent and less than about 20 atomic percent in one embodiment, greater than about 1 atomic percent and less than about 15 atomic percent in another embodiment, or greater than about 1 atomic percent and less than about 8 atomic percent in a further embodiment. It is noted that the concentration of tellurium, selenium, or both can vary through the thickness of the absorber layer 160. For example, when the absorber layer 160 comprises a compound including selenium at a mole fraction of x and tellurium at a mole fraction of 1−x (SeₓTe₁₋ₓ), x can vary in the absorber layer 160 with distance from the first surface 162 of the absorber layer 160.

In some embodiments, the value of x can decrease in the absorber layer 160 with distance from the first surface 162 of the absorber layer 160. For example, a maximum value of the mole fraction x can be within about 1,000 nm of the first surface 162 of the absorber layer 160 such as, for example, within about 500 nm in one embodiment, or within about 250 nm in another embodiment. According to the embodiments provided herein, the maximum value of the mole fraction x can be less than about 0.40 such as, for example, the maximum value of the mole fraction x can be greater than about 0.05 and less than about 0.40 in one embodiment, or the maximum value of the mole fraction x can be greater than about 0.05 and less than about 0.25 in another embodiment. Alternatively or additionally, a minimum value of the mole fraction x can be within about 1,000 nm of the second surface 164 of the absorber layer 160. According to the embodiments provided herein, the minimum value of the mole fraction x can be less than about 0.05 such as, for example, the minimum value of the mole fraction x can be greater than 0 and less than about 0.04 in one embodiment, or the minimum value of the mole fraction x can be greater than 0 and less than about 0.02 in another embodiment.

In embodiments where the absorber layer 160 comprises mercury and cadmium, the atomic percent of the mercury can be greater than about 0 atomic percent and less than about 25 atomic percent such as, for example, greater than about 0.05 atomic percent and less than about 15 atomic percent in one embodiment, greater than about 1 atomic percent and less than about 10 atomic percent in another embodiment, or greater than about 1 atomic percent and less than about 5 atomic percent in a further embodiment. For example, when the absorber layer 160 comprises a compound including mercury at a mole fraction of y and cadmium at a mole fraction of 1−y (Hg_{y}Cd_{1-y}), the mole fraction y can vary in the absorber layer 160 with distance from the first surface 162 of the absorber layer 160.

In some embodiments, the value of the mole fraction y can decrease in the absorber layer 160 with distance from the first surface 162 of the absorber layer 160. For example, the value of the mole fraction y can decrease substantially exponentially with distance from the first surface 162 of the absorber layer 160. A maximum value of the mole fraction y can be within about 1,000 nm of the first surface 162 of the absorber layer 160 such as, for example, within about 500 nm in one embodiment, or within about 250 nm in another embodiment. According to the embodiments provided herein, the maximum value of the mole fraction y can be less than or equal to about 0.4 such as, for example, the maximum value of the mole fraction y can be greater than about 0.005 and less than about 0.15 in one embodiment, or the maximum value of the mole fraction y can be greater than about 0.005 and less than about 0.05 in one embodiment. Alternatively or additionally, a minimum value of the mole fraction y can be within about 1,000 nm of the second surface 164 of the absorber layer 160. According to the embodiments provided herein, the minimum value of the mole fraction y can be less than about 0.04 such as, for example, the minimum value of the mole fraction y can be greater than 0 and less than about 0.03 in one embodiment, or the minimum value of the mole fraction y can be greater than 0 and less than about 0.01 in another embodiment.

In some embodiments, the average concentration of mercury within a central region 166 of the absorber layer 160 can be controlled. The central region 166 is the middle 50% of the absorber layer 160, which is offset by 25% of the thickness of the absorber layer 160 from each of the first surface 162 and the second surface 164 of the absorber layer 160. The average concentration of mercury within the central region 166 of the absorber layer 160 can be greater than about 1×10¹⁹ cm⁻³ such as, for example, greater than about 5×10¹⁹ cm⁻³ and less than about 5×10²¹ cm⁻³ in one embodiment, or greater than about 9×10¹⁹ cm⁻³ and less than about 6×10²⁰ cm⁻³ in another embodiment.

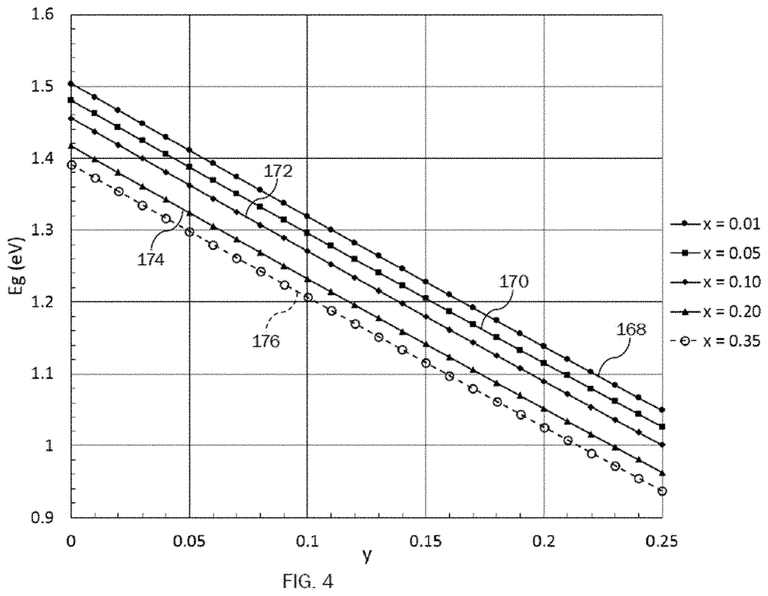

Referring collectively to FIGS. 1 and 3, in some embodiments, the absorber layer 160 can comprise a compound including mercury, cadmium, and tellurium (e.g., Hg_{y}Cd_{1-y}Te). In a Hg_{y}Cd_{1-y}Te compound the band gap Eg of the compound can be adjusted by changing the mole fraction y. As is noted above, the value of y can decrease in the absorber layer 160 with distance from the first surface 162 of the absorber layer 160. Accordingly, the band gap Eg can increase with distance from the first surface 162 of the absorber layer 160. For example, the band gap Eg can increase substantially linearly with distance from the first surface 162 of the absorber layer 160. A minimum value of the band gap Eg can be within about 1,000 nm of the first surface 162 of the absorber layer 160 such as, for example, within about 500 nm in one embodiment, or within about 250 nm in another embodiment. According to the embodiments provided herein, the minimum value of the band gap Eg can be greater than about 0.5 eV and less than about 1.5 eV such as, for example, the minimum value of the band gap Eg can be greater than about 0.8 eV and less than about 1.5 eV in one embodiment, the minimum value of the band gap Eg can be greater than about 1.0 eV and less than about 1.4 eV in another embodiment, or the minimum value of the band gap Eg can be greater than about 1.15 eV and less than about 1.35 eV in a further embodiment.

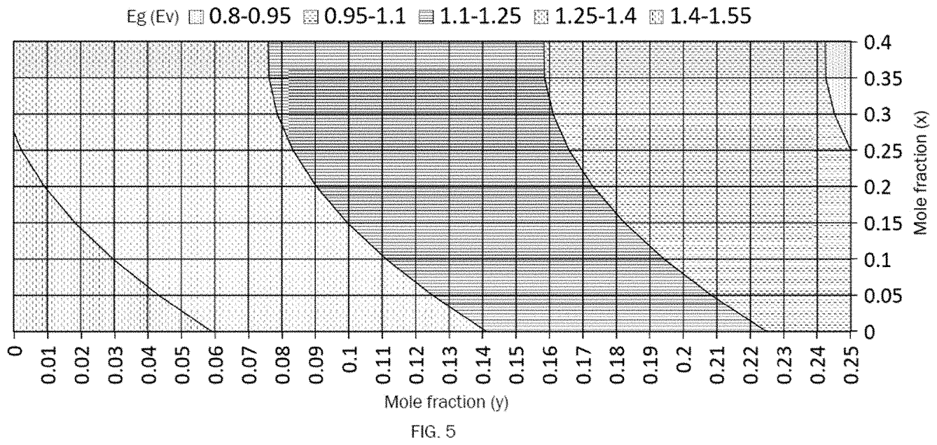

Referring collectively to FIGS. 1 and 4, in some embodiments, the absorber layer 160 can comprise a compound including mercury, cadmium, selenium and tellurium (e.g., Hg_{y}Cd_{1-y}SeₓTe₁₋ₓ). In a Hg_{y}Cd_{1-y}SeₓTe₁₋ₓ compound the band gap Eg of the compound can be adjusted by changing the mole fractions x and y. For example, a first curve 168 depicts a change in band gap Eg of a Hg_{y}Cd_{1-y}SeₓTe₁₋ₓ compound where the mole fraction x is substantially constant at about 0.01 and the mole fraction y varies between about 0 and about 0.25. The resultant band gap Eg is between about 1.50 eV and about 1.05 eV. A second curve 170 depicts a change in band gap Eg of a Hg_{y}Cd_{1-y}SeₓTe₁₋ₓ compound where the mole fraction x is substantially constant at about 0.05 and the mole fraction y varies between about 0 and about 0.25. The resultant band gap Eg is between about 1.48 eV and about 1.03 eV. A third curve 172 depicts a change in band gap Eg of a Hg_{y}Cd_{1-y}SeₓTe₁₋ₓ, compound where the mole fraction x is substantially constant at about 0.10 and the mole fraction y varies between about 0 and about 0.25. The resultant band gap Eg is between about 1.46 eV and about 1.0 eV. A fourth curve 174 depicts a change in band gap Eg of a Hg_{y}Cd_{1-y}SeₓTe₁₋ₓ compound where the mole fraction x is substantially constant at about 0.20 and the mole fraction y varies between about 0 and about 0.25. The resultant band gap Eg is between about 1.42 eV and about 0.96 eV. A fifth curve 176 depicts a change in band gap Eg of a Hg_{y}Cd_{1-y}SeₓTe₁₋ₓ compound where the mole fraction x is substantially constant at about 0.35 and the mole fraction y varies between about 0 and about 0.25. The resultant band gap Eg is between about 1.39 eV and about 0.94 eV. It is noted that, while FIG. 4 depicts curves having substantially constant values for the mole fraction x, either or both of the mole fractions x and y of the Hg_{y}Cd_{1-y}SeₓTe₁₋ₓ compounds provided herein can be varied with thickness in the absorber layer 160.

Referring collectively to FIGS. 1 and 5, a surface map of band gaps corresponding to various Hg_{y}Cd_{1-y}SeₓTe₁₋ₓ compounds is schematically depicted. Specifically, band gaps are provided in units of eV for Hg_{y}Cd_{1-y}SeₓTe₁₋ₓ compounds having various mole fractions x and y, where the mole fraction y is provided along the abscissa and the mole fraction x is provided along the ordinate. The mole fraction y is varied from about 0 to about 0.25 and the mole fraction x is varied from about 0 to about 0.40 to define Hg_{y}Cd_{1-y}SeₓTe₁₋ₓ compounds having band gaps Eg of between about 0.8 eV and about 1.55 eV.

In some embodiments, the sum of the mole fractions x and y can decrease in the absorber layer 160 with distance from the first surface 162 of the absorber layer 160. For example, the sum of the mole fractions x and y can decrease substantially exponentially with distance from the first surface 162 of the absorber layer 160. A maximum value of the sum of the mole fractions x and y can be within about 1,000 nm of the first surface 162 of the absorber layer 160 such as, for example, within about 500 nm in one embodiment, or within about 250 nm in another embodiment. According to the embodiments provided herein, the maximum value of the sum of the mole fractions x and y can be less than or equal to about 0.4 such as, for example, the maximum value of the sum of the mole fractions x and y can be greater than about 0.01 and less than about 0.35 in one embodiment, or the maximum value of the sum of the mole fractions x and y can be greater than about 0.05 and less than about 0.25 in one embodiment. Alternatively or additionally, a minimum value of sum of the mole fractions x and y can be within about 1,000 nm of the second surface 164 of the absorber layer 160. According to the embodiments provided herein, the minimum value of the sum of the mole fractions x and y can be less than about 0.05 such as, for example, the minimum value of the sum of the mole fractions x and y can be greater than 0 and less than about 0.03 in one embodiment, or the minimum value of the sum of the mole fractions x and y can be greater than 0 and less than about 0.01 in another embodiment.

The absorber layer 160 can include a first region 177 and a second region 178, which are non-overlapping. The first region 177 can be disposed closer to the first surface 162 of the absorber layer 160 relative to the second region 178. In some embodiments, the first surface 162 can bound the first region 177. Likewise, the second region 178 can be disposed closer to the second surface 164 of the absorber layer 160 relative to the first region 177. In some embodiments, the second surface 164 can bound the second region 178. According to the embodiments provided herein, a ratio of the average atomic concentration of selenium in the first region 122 to the average atomic concentration of selenium in the second region 124 is greater than about 2. In some embodiments, a ratio of an average of the sum of the mole fractions x and y in the first region 177 to the average of the sum of the mole fractions x and y in the second region 178 is greater than about 5 such as, for example, greater than about 8 in one embodiment, or greater than about 11 in another embodiment.

The first region 177 and the second region 178 can be further characterized by their thickness. In some embodiments, the first region 177 can have a thickness greater than about 100 nanometers and less than about 2,500 nanometers such as, for example, greater than about 150 nanometers and less than about 1,000 nanometers in one embodiment, or greater than about 200 nanometers and less than about 500 nanometers in another embodiment. In some embodiments, the second region 178 can have a thickness greater than about 100 nanometers and less than about 2,500 nanometers such as, for example, greater than about 150 nanometers and less than about 1,000 nanometers in one embodiment, or greater than about 200 nanometers and less than about 500 nanometers in another embodiment. Optionally, the first region 177 can have a larger thickness than the second region 178. Alternatively, the first region 177 can have a smaller thickness than the second region 178.

According to the embodiments provided herein, the dopant within the absorber layer 160 can be activated to a desired charge carrier concentration. In some embodiments, the absorber layer 160 can be doped with a group V dopant such as, for example, nitrogen (N), phosphorous (P), arsenic (As), antimony (Sb), bismuth (Bi), ununpentium (Uup), or a combination thereof. The total dosage of the dopant within the absorber layer 160 can be controlled. Alternatively or additionally, the concentration profile of the group V dopant can vary through the thickness of the absorber layer 160.

Referring again to FIG. 1, the p-n junction can be formed by providing the absorber layer 160 sufficiently close to a portion of the photovoltaic device 100 having an excess of negative charge carriers, i.e., electrons or donors. In some embodiments, the absorber layer 160 can be provided adjacent to n-type semiconductor material. Alternatively, one or more intervening layers can be provided between the absorber layer 160 and n-type semiconductor material. In some embodiments, the absorber layer 160 can be provided adjacent to the buffer layer 150. For example, the first surface 162 of the absorber layer 160 can be provided upon the second surface 154 of the buffer layer 150.

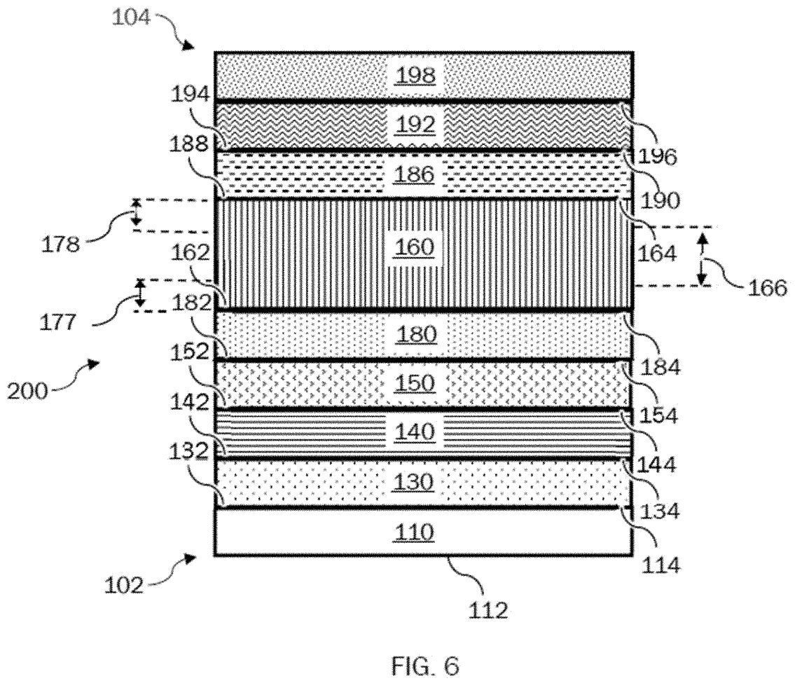

Referring now to FIG. 6, in some embodiments, a photovoltaic device 200 can include a window layer 180 comprising n-type semiconductor material. Aside from the window layer 180, the photovoltaic device 200 can have a substantially similar layer structure as the photovoltaic device 100 (FIG. 1). The absorber layer 160 can be formed adjacent to the window layer 180. The window layer 180 can have a first surface 182 substantially facing the energy side 102 of the photovoltaic device 200 and a second surface 184 substantially facing the opposing side 104 of the photovoltaic device 200. In some embodiments, the window layer 180 can be positioned between the absorber layer 160 and the TCO layer 140. In one embodiment, the window layer 180 can be positioned between the absorber layer 160 and the buffer layer 150. The window layer 180 can include any suitable material, including, for example, cadmium sulfide, zinc sulfide, cadmium zinc sulfide, zinc magnesium oxide, or any combination thereof.

Referring again to FIG. 1, the photovoltaic device 100 can include a back contact layer 186 configured to mitigate undesired alteration of the dopant and to provide electrical contact to the absorber layer 160. The back contact layer 186 can have a first surface 188 substantially facing the energy side 102 of the photovoltaic device 100 and a second surface 190 substantially facing the opposing side 104 of the photovoltaic device 100. A thickness of the back contact layer 186 can be defined between the first surface 188 and the second surface 190. The thickness of the back contact layer 186 can be between about 5 nm to about 200 nm such as, for example, between about 10 nm to about 50 nm in one embodiment.

In some embodiments, the back contact layer 186 can be provided adjacent to the absorber layer 160. For example, the first surface 188 of the back contact layer 186 can be provided upon the second surface 164 of the absorber layer 160. In some embodiments, the back contact layer 186 can include binary or ternary combinations of materials from groups I, II, VI, such as for example, one or more layers containing zinc, copper, cadmium and tellurium in various compositions. Further exemplary materials include, but are not limited to, zinc telluride doped with copper telluride, or zinc telluride alloyed with copper telluride.

The photovoltaic device 100 can include a conducting layer 192 configured to provide electrical contact with the absorber layer 160. The conducting layer 192 can have a first surface 194 substantially facing the energy side 102 of the photovoltaic device 100 and a second surface 196 substantially facing the opposing side 104 of the photovoltaic device 100. In some embodiments, the conducting layer 192 can be provided adjacent to the back contact layer 186. For example, the first surface 194 of the conducting layer 192 can be provided upon the second surface 190 of the back contact layer 186. The conducting layer 192 can include any suitable conducting material such as, for example, one or more layers of nitrogen-containing metal, silver, nickel, copper, aluminum, titanium, palladium, chrome, molybdenum, gold, or the like. Suitable examples of a nitrogen-containing metal layer can include aluminum nitride, nickel nitride, titanium nitride, tungsten nitride, molybdenum nitride, selenium nitride, tantalum nitride, or vanadium nitride.

The photovoltaic device 100 can include a back support 198 configured to cooperate with the substrate 110 to form a housing for the photovoltaic device 100. The back support 198 can be disposed at the opposing side 104 of the photovoltaic device 100. For example, the back support 198 can be formed adjacent to conducting layer 192. The back support 198 can include any suitable material, including, for example, glass (e.g., soda-lime glass).

Referring again to FIG. 1, manufacturing of a photovoltaic device 100, 200 generally includes sequentially disposing functional layers or layer precursors in a “stack” of layers through one or more processes, including, but not limited to, sputtering, spray, evaporation, molecular beam deposition, pyrolysis, closed space sublimation (CSS), pulse laser deposition (PLD), chemical vapor deposition (CVD), electrochemical deposition (ECD), atomic layer deposition (ALD), or vapor transport deposition (VTD). Once a layer is formed it may be desirable to modify the physical characteristics of the layer through subsequent treatment processes.

Referring collectively to FIGS. 1, 7, and 8, a method 210 for forming an absorber layer 160 is depicted. The method 210 can include a process 212 for forming a precursor layer stack 220. For example, the precursor layer stack 220 can be used to from a Hg_{y}Cd_{1-y}SeₓTe₁₋ₓ compound. In some embodiments, the precursor layer stack 220 can be disposed adjacent to the buffer layer 150 (FIG. 1) or the window layer 180 (FIG. 6). Specifically, the precursor layer stack 220 can include a first surface 222 corresponding to the first surface 162 of the absorber layer 160, and a second surface 224 corresponding to the second surface 164 of the absorber layer 160. A thickness of the precursor layer stack 220 can be bounded by the first surface 222 and the second surface 224.

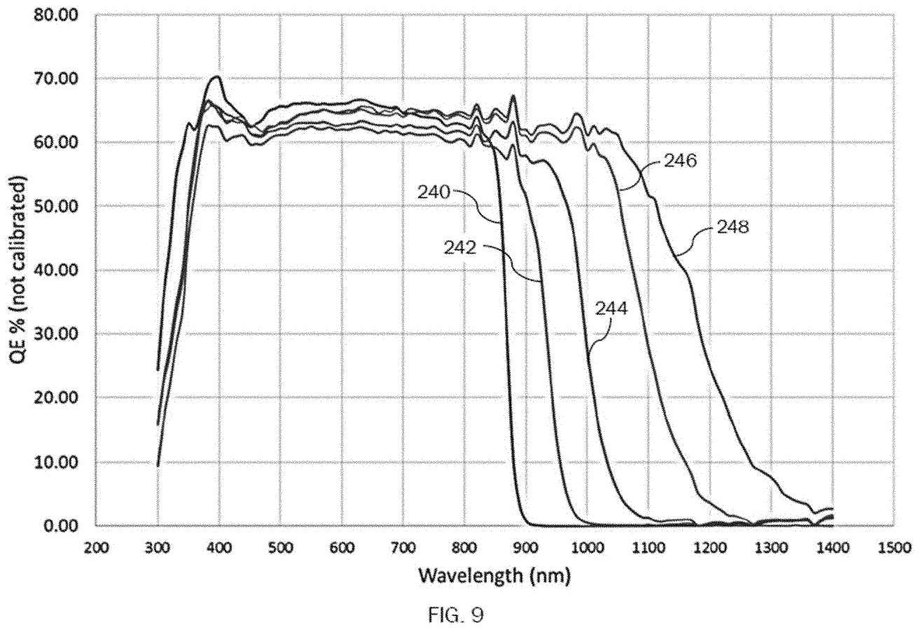

Referring to FIG. 8, the precursor layer stack 220 can include a mercury containing layer 230 located between the first surface 222 and the second surface 224. The mercury containing layer 230 can be formed from or consist of Hg or a mercury containing compound such as, for example, HgS, HgSe, HgTe, or the like. The mercury containing layer 230 can have a thickness greater than about 10 nm and less than about 1,000 nm, such as for example, greater than about 10 nm and less than about 300 nm in one embodiment, greater than about 20 nm and less than about 200 nm in another embodiment, greater than about 25 nm and less than about 150 nm in yet another embodiment, or greater than about 30 nm and less than about 75 nm in a further embodiment.

Referring collectively to FIGS. 1, 4, 8, and 9, a bandwidth of the quantum efficiency QE for the photovoltaic device 100 can be extended by increasing the thickness of the mercury containing layer 230. FIG. 9 graphically depicts the bandwidth of quantum efficiency QE of devices having maximum mole fractions x and y found along the fourth curve 174 of FIG. 4. Specifically, the first curve 240 can correspond a photovoltaic device without a mercury containing layer 230 and a maximum mole fraction x of about 0.20. A second curve 242 can correspond to a mercury containing layer 230 with a thickness of about 50 nm, a maximum mole fraction x of about 0.20, and a maximum mole fraction y of about 0.06. A third curve 244 can correspond to a mercury containing layer 230 with a thickness of about 100 nm, a maximum mole fraction x of about 0.20, and a maximum mole fraction y of about 0.10. A fourth curve 246 can correspond to a mercury containing layer 230 with a thickness of about 150 nm, a maximum mole fraction x of about 0.20, and a maximum mole fraction y of about 0.17. A fifth curve 248 can correspond to a mercury containing layer 230 with a thickness of about 200 nm, a maximum mole fraction x of about 0.20, and a maximum mole fraction y of about 0.21.

Referring again to FIG. 8, the first surface 222 of the precursor layer stack 220 can be formed by a first layer 230 comprising or consisting essentially of CdSe. The mercury containing layer 232 can be disposed adjacent to the first layer 232. A capping layer 234 can be disposed adjacent to the mercury containing layer 232. The capping layer 234 can be formed from a mercury free material configured to limit the diffusion of mercury towards the second surface 224 such as, for example, CdSe, CdTe, or the like. A bulk layer 236 can be provided adjacent to the capping layer 234. The bulk layer 236 can comprise or can consist essentially of CdTe. Generally, the thickness of the bulk layer 236 is larger than a sum of the thicknesses of the first layer 232, the mercury containing layer 230, and the capping layer 234. A ratio of the thickness of the bulk layer 236 to the sum of the thicknesses of the first layer 232, the mercury containing layer 230, and the capping layer 234 can be greater than about 4 such as, for example, greater than about 7 in one embodiment, or greater than about 10 in another embodiment.

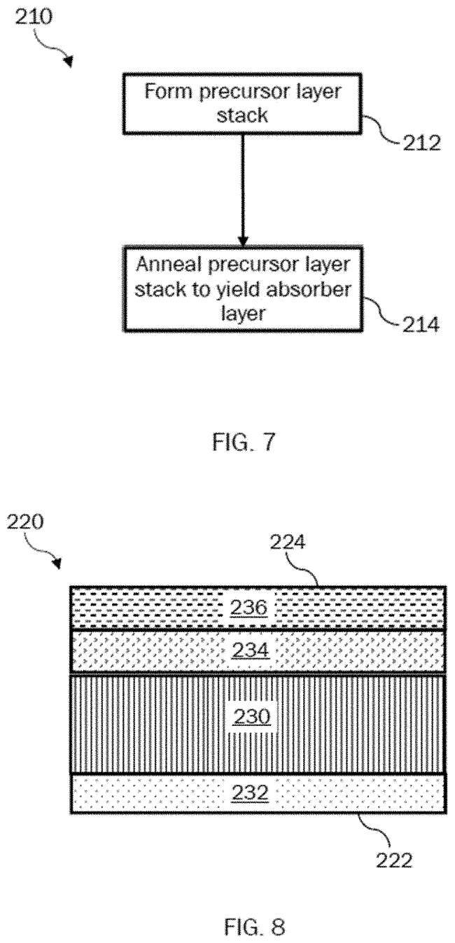

Referring collectively to FIGS. 7 and 8, the method 210 can include a process 214 for annealing the precursor layer stack 220. In some embodiments, cadmium chloride (CdCl₂) can be applied to the second surface 224 of the precursor layer stack 220 as a solution. For example, the solution can be sprayed, spin coated, or roll coated upon the precursor layer stack 220. Alternatively or additionally, the solution can be supplied as a vapor. Generally, annealing includes heating the precursor layer stack 220 (e.g., polycrystalline semiconductor material) for sufficient time and temperature to facilitate re-crystallization of the precursor layer stack 220 to yield the absorber layer 160. For example, the precursor layer stack 220 can be processed at a temperature between about 350° C. and about 500° C. for between about 5 minutes and about 60 minutes such as, for example, at a temperature in a range of about 400° C. to about 500° C. for a duration of about 10 minutes to about 55 minutes in one embodiment. In addition to recrystallization, the materials of the precursor layer stack 220 can diffuse throughout the absorber layer 160, as is explained in greater detail herein above.

### Example

Referring collectively to FIGS. 1 and 8, an embodiment of the photovoltaic device 100 was formed. The precursor layer stack 220 was formed from a first layer 232 having CdSe with a thickness of about 50 nm, a mercury containing layer 230 having HgSe with a thickness of about 50 nm, a capping layer 234 having CdSe with a thickness of about 50 nm, and a bulk layer 236 of CdTe having a thickness of about 3 μm. The example embodiment was annealed as described herein. The example embodiment had an increased efficiency as compared to a corresponding device produced without mercury, i.e., an incremental improvement of about 1% in efficiency (about a 5% improvement).

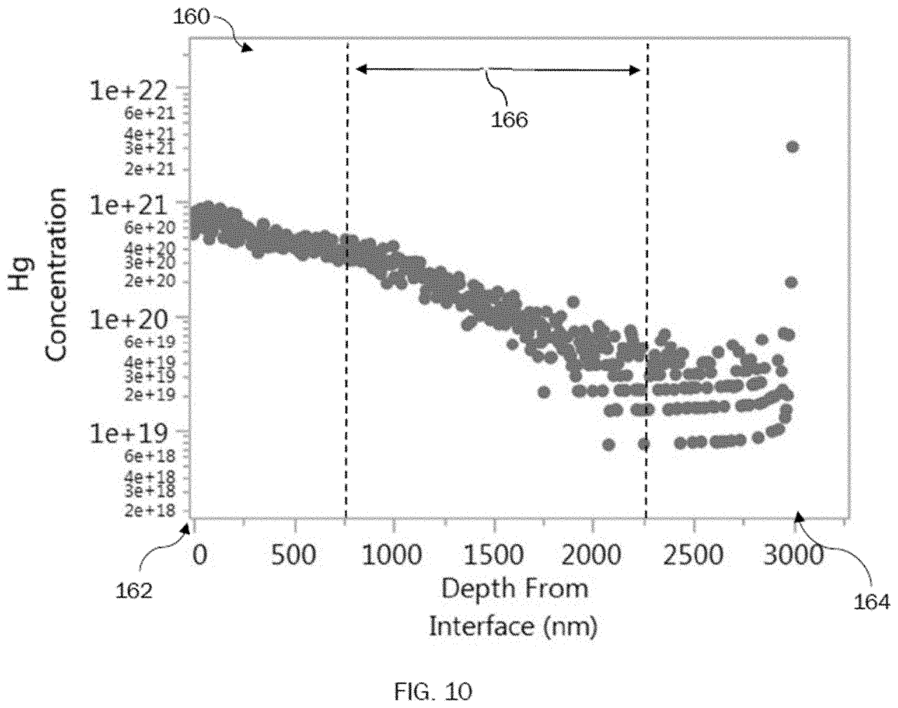

Referring now to FIG. 10, the example embodiment resulted in an absorber layer 160 having a graded concentration of mercury through the absorber layer 160. The concentration of mercury was determined using Time-of-Flight Secondary Ion Mass Spectrometry (ToF-SIMS). Accordingly, the measurements at the second surface 164 of the absorber layer 160 can be relatively susceptible to noise. The central region 166 had an average concentration of mercury of about 1.5×10²⁰ cm³. The concentration of mercury generally decreased from the first surface 162 towards the second surface 164.

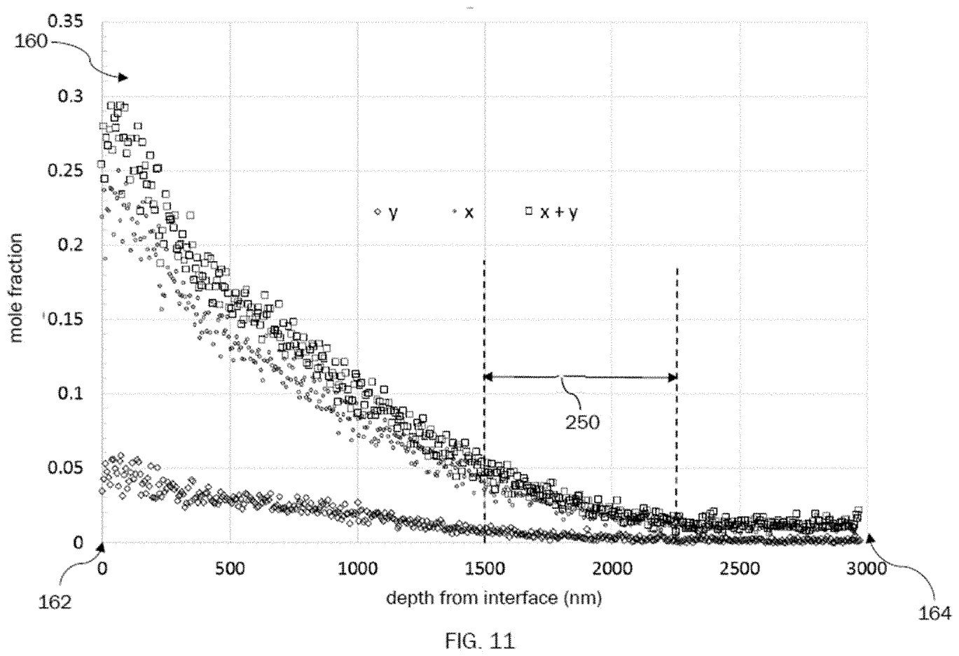

Referring now to FIG. 11, the example embodiment resulted in an absorber layer 160 having a Hg_{y}Cd_{1-y}SeₓTe₁₋ₓ compound with a varying mole fractions x and y. The mole fractions x and y were calculated from ToF-SIMS. The maximum of the mole fraction x was about 0.25 and located near the first surface 162 of the absorber layer 160. The maximum of the mole fraction y was about 0.06 and located near the first surface 162 of the absorber layer 160. The maximum of the sum of the mole fractions x and y was about 0.30 and located near the first surface 162 of the absorber layer 160. The average of the sum of the mole fractions x and y in the third quartile 250 of the absorber layer 160 was between about 0.01 and about 0.05.

It should now be understood that the embodiments provided herein, relate to absorber layers comprising mercury, cadmium and tellurium that improve device efficiency. Additionally, the amount and profile of mercury and/or selenium can be controlled to limit the number of defects within the absorber layer associated with the use of selenium, mercury, or both.

According to the embodiments provided herein, a photovoltaic device can have an energy side configured to be exposed to a light source. The photovoltaic device can include an absorber layer. The absorber layer can include a first surface facing the energy side and a thickness defined between the first surface and a second surface. The absorber layer can include mercury having a mole fraction y, cadmium having a mole fraction (1−y), and tellurium. The mole fraction y of the mercury can vary through the thickness of the absorber layer with distance from the first surface of the absorber layer. A band gap of the absorber layer at the first surface can be greater than 0.5 eV and less than 1.5 eV.

According to the embodiments provided herein, a method for forming an absorber layer can include forming a precursor layer stack. The precursor layer stack can include a mercury containing layer located between a first surface of the precursor layer stack and the second surface of the precursor layer stack. The mercury containing layer can have a thickness greater than 10 nm and less than 1,000 nm. The method can also include annealing the precursor layer stack, whereby the absorber layer is formed from the precursor layer stack.

It is noted that the terms “substantially” and “about” may be utilized herein to represent the inherent degree of uncertainty that may be attributed to any quantitative comparison, value, measurement, or other representation. These terms are also utilized herein to represent the degree by which a quantitative representation may vary from a stated reference without resulting in a change in the basic function of the subject matter at issue.

While particular embodiments have been illustrated and described herein, it should be understood that various other changes and modifications may be made without departing from the spirit and scope of the claimed subject matter. Moreover, although various aspects of the claimed subject matter have been described herein, such aspects need not be utilized in combination. It is therefore intended that the appended claims cover all such changes and modifications that are within the scope of the claimed subject matter.

What is claimed is:

1. A photovoltaic device having an energy side configured to be exposed to a light source, the photovoltaic device comprising an absorber layer, wherein:
the absorber layer comprises a first surface facing the energy side and a thickness defined between the first surface and a second surface;
the absorber layer comprises mercury having a mole fraction y, cadmium having a mole fraction (1−y), and tellurium;
the mole fraction y of the mercury varies through the thickness of the absorber layer with distance from the first surface of the absorber layer; and
a band gap of the absorber layer at the first surface is greater than 0.5 eV and less than 1.5 eV.

2. The photovoltaic device of claim 1, wherein:
the absorber layer has a central region forming the middle 50% of the thickness of the absorber layer; and
an average concentration of mercury within the central region of the absorber layer is greater than 1×10¹⁹ cm⁻³.

3. The photovoltaic device of claim 1, wherein an atomic percent of the tellurium in the absorber layer is greater than 25 atomic percent and less than 50 atomic percent.

4. The photovoltaic device of claim 1, wherein an atomic percent of the mercury in the absorber layer is greater than 0 atomic percent and less than 25 atomic percent.

5. The photovoltaic device of claim 1, wherein a minimum of the mole fraction y of the mercury is less than 0.04.

6. The photovoltaic device of claim 5, wherein the minimum of the mole fraction y of the mercury is within 1,000 nm of the second surface of the absorber layer.

7. The photovoltaic device of claim 1, wherein a maximum of the mole fraction y of the mercury is less than 0.4.

8. The photovoltaic device of claim 7, wherein the maximum of the mole fraction y of the mercury is within 1,000 nm of the first surface of the absorber layer.

9. The photovoltaic device of claim 1, wherein:
the absorber layer comprises selenium;
the mercury, the cadmium, the selenium, and the tellurium form a Hg_{y}Cd_{1-y}SeₓTe₁₋ₓ compound;
the selenium has a mole fraction x, and the tellurium has a mole fraction (1−x); and
the mole fraction x of the selenium varies through the thickness of the absorber layer with distance from the first surface of the absorber layer.

10. The photovoltaic device of claim 9, wherein a minimum of the mole fraction x of the selenium is less than 0.05.

11. The photovoltaic device of claim 10, wherein the minimum of the mole fraction x of the selenium is within 1,000 nm of the second surface of the absorber layer.

12. The photovoltaic device of claim 9, wherein a maximum of the mole fraction x of the selenium is less than 0.4.

13. The photovoltaic device of claim 12, wherein the maximum of the mole fraction x of the selenium is within 1,000 nm of the first surface of the absorber layer.

14. The photovoltaic device of claim 9, wherein an atomic percent of the selenium in the absorber layer is greater than 0 atomic percent and less than 25 atomic percent.

15. The photovoltaic device of claim 9, wherein a sum of the mole fraction x of the selenium and the mole fraction y of the mercury decreases with distance from the first surface of the absorber layer.

16. The photovoltaic device of claim 9, wherein a minimum of a sum of the mole fraction x of the selenium and the mole fraction y of the mercury is less than 0.05.

17. The photovoltaic device of claim 9, wherein a maximum of a sum of the mole fraction x of the selenium and the mole fraction y of the mercury is less than 0.4.

18. The photovoltaic device of claim 9, wherein:
the absorber layer comprises a first region and a second region;
the first region is disposed closer to the first surface of the absorber layer relative to the second region; and
a ratio of an average of a sum of the mole fraction x of the selenium and the mole fraction y of the mercury in the first region to an average of a sum of the mole fraction x of the selenium and the mole fraction y is greater than 5.

19. The photovoltaic device of claim 18, wherein the first region and the second region have a thickness greater than 100 nanometers and less than 2,500.

20. The photovoltaic device of claim 1, wherein the absorber layer is doped p-type, and comprises a group I dopant, a group V dopant, or both.

21-43. (canceled)
